(19) United States
(12) Patent Application Publication
(10) Pub. No.: US 2024/0007073 A1
(43) Pub. Date: Jan. 4, 2024

(54) FILM BULK ACOUSTIC RESONATOR AND MANUFACTURING METHOD THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/335,780

(22) Filed: Jun. 15, 2023

(30) Foreign Application Priority Data
Jun. 30, 2022 (CN) 202210762327.7

(51) Int. Cl. H03H 3/02; H03H 9/17; H03H 9/13

(52) U.S. Cl. CPC H03H 3/02; H03H 9/173; H03H 2003/021; H03H 9/131; H03H 9/176

(57) ABSTRACT

Disclosed are a film bulk acoustic resonator and a manufacturing method therefor. The film bulk acoustic resonator includes: a substrate, a buffer layer, a first electrode layer, a piezoelectric layer, a second electrode layer stacked in sequence, and a cavity structure arranged between the substrate and the first electrode layer and at least partially located in the buffer layer, where the first electrode layer includes an N-type semiconductor. The N-type semiconductor has an integrated structure and may be used as an electrode, so that the cavity structure at least partially located in the buffer layer may be formed first, and then the N-type semiconductor is arranged on the cavity structure. Thus, there is no need to etch sacrificial materials to form the cavity structure, thereby reducing probability of device reliability deterioration due to etching sacrificial materials.

### CROSS-REFERENCE TO RELATED APPLICATIONS

The application claims priority to Chinese Patent Application No. 202210762327.7, filed on Jun. 30, 2022, which is hereby incorporated by reference in its entirety.

### TECHNICAL FIELD

The present disclosure relates to the field of filter technologies, and in particular, to a film bulk acoustic resonator and a manufacturing method therefor.

### BACKGROUND

As for a film bulk acoustic resonator (FBAR), an interface between air and an electrode needs to be formed below a piezoelectric layer for operation. In the conventional art, the interface between the air and the electrode is formed by forming a sacrificial material first, then preparing the piezoelectric layer, and finally etching the sacrificial material away to prepare a cavity structure.

However, no matter what kind of etching method is used, other device materials covering the sacrificial material may be damaged to varying degrees, affecting a reliability of the device.

### SUMMARY

In view of this, embodiments of the present disclosure provide a film bulk acoustic resonator and a manufacturing method therefor, to solve a technical problem that a reliability of a device is affected by etching on a sacrificial material in the conventional art.

According to an aspect of the present disclosure, an embodiment of the present disclosure provides a film bulk acoustic resonator. The film bulk acoustic resonator includes: a substrate, a buffer layer, a first electrode layer, a piezoelectric layer, a second electrode layer stacked in sequence, and a cavity structure arranged between the substrate and the first electrode layer and at least partially located in the buffer layer, where the first electrode layer includes an N-type semiconductor.

In an embodiment, the cavity structure includes: a through slot penetrating through the buffer layer in a direction perpendicular to a plane where the substrate is located.

In an embodiment, the first electrode layer further includes: a metal synergistic resistance reduction layer disposed on a side, close to the buffer layer, of the N-type semiconductor.

In an embodiment, the metal synergistic resistance reduction layer includes any one of a molybdenum (Mo) layer, a cerium (Ce) layer, and a cobalt (Co) layer.

In an embodiment, the N-type semiconductor includes an N-type silicon carbide substrate or a heavily-doped N-type silicon carbide substrate.

In an embodiment, the second electrode layer includes: a metal sub-layer and a heavily-doped semiconductor stacked in sequence, and the metal sub-layer is located on a side, away from the substrate, of the heavily-doped semiconductor.

In an embodiment, a material of the metal sub-layer includes aluminum (Al) or copper (Cu).

In an embodiment, a material of the heavily-doped semiconductor includes a heavily-doped gallium nitride or a heavily-doped aluminum gallium nitride.

In an embodiment, a material of the buffer layer includes silicon dioxide.

In an embodiment, a material of the piezoelectric layer includes aluminum nitride.

According to another aspect of the present disclosure, an embodiment of the present disclosure provides a manufacturing method for a film bulk acoustic resonator. The manufacturing method for the film bulk acoustic resonator includes: forming a buffer layer on a substrate; forming a cavity structure by using an etching process; and forming a first electrode layer, a piezoelectric layer and a second electrode layer on a side, away from the substrate, of the buffer layer, where the substrate, the buffer layer, the first electrode layer, the piezoelectric layer and the second electrode layer are stacked in sequence, the cavity structure is arranged between the substrate and the first electrode layer, at least part of the cavity structure is located in the buffer layer, and the first electrode layer includes an N-type semiconductor.

In an embodiment, the forming a cavity structure by using an etching process includes: at least etching the buffer layer by using a dry etching method or a photolithography method, until at least part of the cavity structure is located in the buffer layer in a direction perpendicular to a plane where the substrate is located, to form the cavity structure.

In an embodiment, the forming a first electrode layer on a side, away from the substrate, of the buffer layer includes: bonding the first electrode layer to the buffer layer.

In an embodiment, the forming a first electrode layer, a piezoelectric layer and a second electrode layer on a side, away from the substrate, of the buffer layer, where the substrate, the buffer layer, the first electrode layer, the piezoelectric layer and the second electrode layer are stacked in sequence includes: sequentially forming, after a stacked structure of the substrate, the buffer layer and the first electrode layer being manufactured, the piezoelectric layer and the second electrode layer on a side, away from the buffer layer, of the first electrode layer.

In an embodiment, the forming a first electrode layer, a piezoelectric layer and a second electrode layer on a side, away from the substrate, of the buffer layer, wherein the substrate, the buffer layer, the first electrode layer, the piezoelectric layer and the second electrode layer are stacked in sequence includes: respectively manufacturing a stacked structure of the substrate and the buffer layer, and a stacked structure of the first electrode layer, the piezoelectric layer and the second electrode layer; and bonding the buffer layer and the first electrode layer face to face.

### BRIEF DESCRIPTION OF THE DRAWINGS

FIG. 1 is a schematic structural diagram of a film bulk acoustic resonator according to an embodiment of the present disclosure.

FIG. 2 is a schematic structural diagram of a film bulk acoustic resonator according to another embodiment of the present disclosure.

FIG. 3 is a schematic structural diagram of a film bulk acoustic resonator according to still another embodiment of the present disclosure.

FIG. 4 is a schematic structural diagram of a film bulk acoustic resonator according to yet still another embodiment of the present disclosure.

FIG. 5 is a schematic structural diagram of a film bulk acoustic resonator according to yet still another embodiment of the present disclosure.

FIG. 6 is a schematic flowchart of a manufacturing method for a film bulk acoustic resonator according to an embodiment of the present disclosure.

FIG. 7 is a schematic flowchart of a manufacturing method for a film bulk acoustic resonator according to another embodiment of the present disclosure.

FIG. 8 (a) to FIG. 8 (d) are schematic flowcharts of a manufacturing method for a film bulk acoustic resonator according to yet still another embodiment of the present disclosure.

FIG. 9 is a schematic flowchart of a manufacturing method for a film bulk acoustic resonator according to yet still another embodiment of the present disclosure.

FIG. 10 is a schematic flowchart of a manufacturing method for a film bulk acoustic resonator according to yet still another embodiment of the present disclosure.

### DETAILED DESCRIPTION OF THE EMBODIMENTS

Technical solutions in the embodiments of the present disclosure will be clearly and completely described with reference to the accompanying drawings in the embodiments of the present disclosure in the following description. Apparently, the described embodiments are only some, not all, embodiments of the disclosure. Based on the embodiments in the present disclosure, all other embodiments obtained by those skilled in the art without making creative efforts fall in the protection scope of the present disclosure.

With development of films and micro-nano manufacturing technologies, a film bulk acoustic resonator is highly favored due to small size, low cost, high quality factor, strong power bearing capacity, high frequency, compatibility with integrated circuit (IC) technologies, and the like. Considering a working principle of the film bulk acoustic resonator, an interface (that is, a cavity structure formed on an upper surface of a substrate) between air and an electrode needs to be formed below a piezoelectric layer for operation.

In the conventional art, sacrificial materials are first filled before preparing a piezoelectric layer, and finally the sacrificial material is etched to prepare a cavity structure to form an air electrode interface. Generally, hydrofluoric acid and phosphoric acid are used to etch silicon dioxide to prepare a cavity. Not only is the process cumbersome, but result wash solution may also pollute the environment. Most importantly, hydrofluoric acid and phosphoric acid have corrosive, which may damage other device materials covering the sacrificial materials, such as an electrode, a piezoelectric layer, and the like, leading to poor device reliability.

In order to solve the problems described above, the present disclosure provides a film bulk acoustic resonator. The film bulk acoustic resonator includes: a substrate, a buffer layer, a first electrode layer, a piezoelectric layer, a second electrode layer stacked in sequence, and a cavity structure, arranged between the substrate and the first electrode layer and at least partially located in the buffer layer, where the first electrode layer includes an N-type semiconductor. The N-type semiconductor has an integrated structure and may be used as an electrode, so that the cavity structure at least partially located in the buffer layer may be formed first, and then the N-type semiconductor is arranged on the cavity structure. Thus, there is no need to etch sacrificial materials to form the cavity structure, thereby reducing probability of device reliability deterioration due to etching sacrificial materials.

The film bulk acoustic resonator and the manufacturing method thereof mentioned in the present disclosure are further illustrated below with reference to FIG. 1 to FIG. 10.

FIG. 1 is a schematic structural diagram of a film bulk acoustic resonator according to an embodiment of the present disclosure. As shown in FIG. 1, the film bulk acoustic resonator includes a substrate 1, a buffer layer 2, a first electrode layer 3, a piezoelectric layer 4, a second electrode layer 5 stacked in sequence, and a cavity structure 6 arranged between the substrate 1 and the first electrode layer 3 and at least partially located in the buffer layer 2. The first electrode layer 3 includes an N-type semiconductor.

The cavity structure 6 at least partially located in the buffer layer 2 refers to that at least a part of the cavity structure 6 is located in the buffer layer 2. That is, the cavity structure 6 may be wholly located in the buffer layer 2, or may be partially located in the buffer layer 2.

Specifically, the cavity structure 6 includes one of following cases.

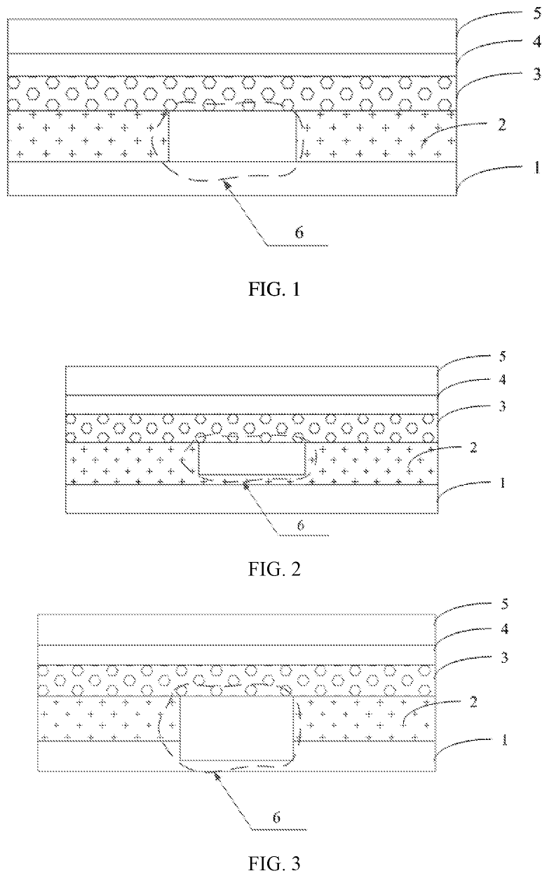

(1) FIG. 2 is a schematic structural diagram of a film bulk acoustic resonator according to another embodiment of the present disclosure. As shown in FIG. 2, a cavity structure 6 is a first slot that is on a side, close to a first electrode layer 3, of a buffer layer 2, and does not penetrate through the buffer layer 2 in a direction perpendicular to a plane where a substrate 1 is located.

Exemplarily, the cavity structure 6 is formed by a dry etching method or a photolithography method, that is, only part of the buffer layer 2 is etched in the direction perpendicular to a plane where the substrate 1 is located to form the first slot, so that the cavity structure 6 is formed.

(2) With reference to FIG. 1, the cavity structure 6 is a through slot penetrating through the buffer layer 2 in a direction perpendicular to a plane where the substrate 1 is located.

That is to say, the cavity structure 6 are totally located in the buffer layer 2.

Exemplarily, the cavity structure 6 is formed by a dry etching method or a photolithography method, that is, in the direction perpendicular to a plane where the substrate 1 is located, the buffer layer 2 is completely etched away to form the through slot, so that the cavity structure 6 is formed. Considering that the buffer layer 2 and the substrate 1 are made of different materials, the cavity structure 6 is only etched to the substrate 1, and the substrate 1 is not etched, thereby facilitating an etching operation.

(3) FIG. 3 is a schematic structural diagram of a film bulk acoustic resonator according to still another embodiment of the present disclosure. As shown in FIG. 3, a cavity structure 6 is composed of a through slot penetrating through a buffer layer 2 in a direction perpendicular to a plane where a substrate 1 is located and a second slot that is on a side, close to the buffer layer 2, of a substrate 1 and does not penetrate through the substrate 1 in the direction perpendicular to the plane where the substrate 1 is located. That is, a part of the cavity structure 6 is located in the buffer layer 2, and the other part is located in the substrate 1.

Exemplarily, the cavity structure 6 is formed by a dry etching method or a photolithography method, that is, in the direction perpendicular to the plane where the substrate 1 is located, the buffer layer 2 is completely etched away to form the through slot, and a part of the substrate 1 is continuously etched in the direction perpendicular to the plane where the substrate 1 is located to form the second slot, so as to form the cavity structure 6.

In the embodiment of the present disclosure, the N-type semiconductor may be used as a substrate material. As the N-type semiconductor has an integrated structure, and may be used as an electrode, the cavity structure 6 at least partially located in a buffer layer 2 may be formed first, and then the N-type semiconductor is arranged on the cavity structure 6. Thus, there is no need to etch sacrificial materials to form the cavity structure, thereby reducing probability of device reliability deterioration due to etching sacrificial materials.

In an embodiment, the N-type semiconductor includes an N-type silicon carbide substrate (that is, an N-type SiC substrate). SiC is commonly used as a substrate material of a semiconductor device, and the N-type SiC substrate is formed by doping N-type impurities. An integrated structure of the N-type SiC substrate is easy to bond with a buffer layer 2 and has a simple process. Since the N-type SiC substrate meets a requirement of serving as an electrode, the N-type SiC substrate may be used to form a first electrode layer 3.

Optionally, other N-type semiconductor materials, such as an N-type GaAs substrate and an N-type GaN substrate, may also be used to form a first electrode layer 3.

In a further embodiment, an N-type semiconductor includes a heavily-doped N-type silicon carbide substrate (denoted as an N++SiC substrate). Due to a doping element in the heavily-doped N-type silicon nitride substrate, surface active sites may be changed, surface activity energy may be improved, electrical resistivity may be reduced, and a stability of a device may be improved.

Exemplarily, doping elements in the heavily-doped N-type silicon carbide substrate include, but are not limited to, phosphorus (P) and nitrogen (N).

Specifically, a doping element in the heavily-doped N-type silicon carbide substrate is P. The heavily-doped N-type silicon carbide substrate is formed by injecting P onto an N-type silicon carbide substrate and then performing annealing at high temperature.

In the embodiment of the present disclosure, by using a heavily doped N-type silicon carbide substrate, electrical resistivity is reduced, thereby improving working performance of a film bulk acoustic resonator and stability of a device.

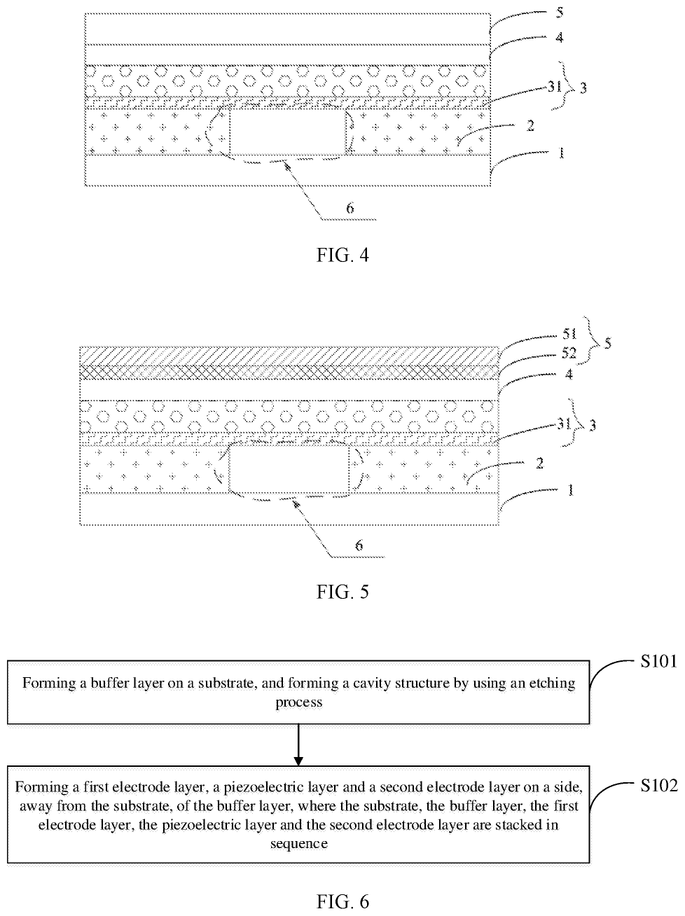

FIG. 4 is a schematic structural diagram of a film bulk acoustic resonator according to yet still another embodiment of the present disclosure. As shown in FIG. 4, a first electrode layer 3 further includes: a metal synergistic resistance reduction layer 31 disposed on a side, close to a buffer layer 2, of an N-type semiconductor.

The metal synergistic resistance reduction layer 31 is configured to generate a synergistic effect with the N-type semiconductor to jointly reduce electrical resistivity.

Exemplarily, the metal synergistic resistance reduction 31 includes, but is not limited to, any one of a molybdenum (Mo) layer, a cerium (Ce) layer, a cobalt (Co) layer, and the like.

Exemplarily, the metal synergistic resistance reduction 31 is the Mo layer, that is, the first electrode layer 3 includes an N-type silicon carbide substrate and the Mo layer disposed on a side, close to the buffer layer 2, of the N-type silicon carbide substrate. A preparation method of the Mo layer is deposition. The Mo layer is deposited on a side of the N-type silicon carbide substrate, and then a side of the first electrode layer 3 close to the Mo layer is bonded to the buffer layer 2, to facilitating epitaxial growth of a piezoelectric layer 4, a second electrode layer 5 and other subsequent structures on a side, away from the Mo layer, of the N-type silicon carbide substrate. Optionally, after the piezoelectric layer 4, the second electrode layer 5 and other structures are epitaxially prepared on a side of the N-type silicon carbide substrate, the Mo layer 31 is deposited on a side, away from the piezoelectric layer 4, of the N-type silicon carbide substrate and then bonded to the buffer layer 2 to form a structure where the Mo layer is located between the N-type silicon carbide substrate and the buffer layer 2. By depositing the Mo layer on the N-type silicon carbide substrate, a synergistic effect is utilized to reduce electrical resistivity and improve stability of the first electrode layer 3.

It should be noted that, the first electrode layer 3 may have a higher resonance frequency with the Mo layer serving as a material of the metal synergistic resistance reduction layer 31 compared with other materials and the N-type semiconductor.

In an optional embodiment, a material of the buffer layer 2 is silicon dioxide (SiO₂).

It should be noted that, SiO₂, as the material of the buffer layer 2, may be etched by using a simple dry etching method or photolithography etching method to form the cavity structure 6 at least partially located in the buffer layer 2 in a direction perpendicular to a plane where the substrate 1 is located.

In an optional embodiment, a material of a piezoelectric layer 4 is aluminum nitride (AlN).

Optionally, single crystal AlN may be selected as the material of the piezoelectric layer 4. A piezoelectric coupling coefficient of the piezoelectric layer 4 may further be improved by doping and ion implantation.

FIG. 5 is a schematic structural diagram of a film bulk acoustic resonator according to yet still another embodiment of the present disclosure. As shown in FIG. 5, a second electrode layer 5 includes a metal sub-layer 51 and a heavily-doped semiconductor 52 stacked in sequence, and the metal sub-layer 51 is located on a side, away from a substrate 1, of the heavily-doped semiconductor 52.

A material of the metal sub-layer 51 includes, but is not limited to, any one of aluminum (Al), copper (Cu), and the like. A material of the heavily-doped semiconductor 52 includes heavily-doped gallium nitride (denoted as N++GaN), or heavily-doped aluminum gallium nitride (denoted as N++AlGaN).

Exemplarily, the second electrode layer 5 includes an Al metal sub-layer and the heavily-doped gallium nitride (N++GaN) semiconductor located on a side, close to a buffer layer 2, of the Al metal sub-layer. The N++GaN semiconductor and the Al metal sub-layer together serve as the second electrode layer 5, and the N++GaN semiconductor directly contacts with a piezoelectric layer 4, so that a contact resistance between the second electrode layer 5 and the piezoelectric layer 4 may be reduced, thereby improving conductivity and stability of a device.

Exemplarily, the second electrode layer 5 includes the Al metal sub-layer and the heavily-doped aluminum gallium nitride (N++AlGaN) semiconductor located on a side, close to the buffer layer 2, of the Al metal sub-layer. The N++AlGaN semiconductor and the Al metal sub-layer together serve as the second electrode layer 5, and the N++AlGaN semiconductor directly contacts with the piezoelectric layer 4, so that the contact resistance of the second electrode layer 5 and the piezoelectric layer 4 may be reduced, thereby improving the conductivity and the stability of a device.

FIG. 6 is a schematic flowchart of a manufacturing method for a film bulk acoustic resonator according to an embodiment of the present disclosure. As shown in FIG. 6, the manufacturing method of the film bulk acoustic resonator includes the following steps.

Step S101: forming a buffer layer on a substrate, and forming a cavity structure by using an etching process.

Step S102: forming a first electrode layer, a piezoelectric layer and a second electrode layer on a side, away from the substrate, of the buffer layer, where the substrate, the buffer layer, the first electrode layer, the piezoelectric layer and the second electrode layer are stacked in sequence.

Exemplarily, the cavity structure 6 is located between the substrate 1 and the first electrode layer 3, and at least part of the cavity structure 6 is located in the buffer layer 2. The first electrode layer 3 includes an N-type semiconductor.

Specifically, a specific positional relationship between the cavity structure 6 and the buffer layer 2 is the same as the structure described above, and details are not described herein.

Specifically, materials of the piezoelectric layer and the second electrode layer are the same as described above, and details are not described herein.

It should be noted that the cavity structure 6 formed in Step S101 is actually a slot located in the buffer layer 2, and a real cavity may be formed only after the first electrode layer 3 is manufactured.

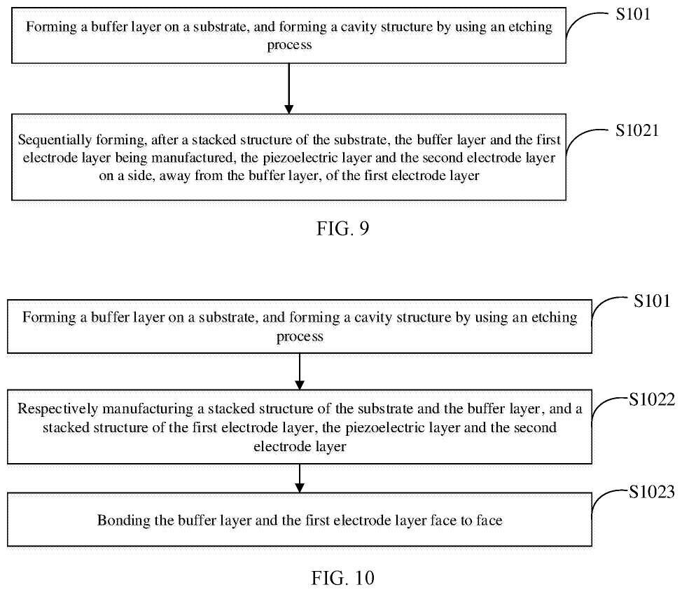

It should be noted that, in Step S102, that the substrate 1, the buffer layer 2, the first electrode layer 3, the piezoelectric layer 4, and the second electrode layer 5 are stacked in sequence only refers to a positional relationship of each structure, and not refers to steps of a manufacturing process of each structure. Optionally, as shown in FIG. 9, the Step 102 includes the following step. Step S1021: sequentially forming, after a stacked structure of the substrate, the buffer layer and the first electrode layer being manufactured, the piezoelectric layer and the second electrode layer on a side, away from the buffer layer, of the first electrode layer. Optionally, as shown in FIG. 10, the Step 102 includes the following step. Step S1022: respectively manufacturing a stacked structure of the substrate and the buffer layer, and a stacked structure of the first electrode layer, the piezoelectric layer and the second electrode layer. Step S1023: bonding the buffer layer and the first electrode layer face to face.

In the embodiments of the present disclosure, the cavity structure 6 at least partially located in the buffer layer 2 is first formed by using an etching method, and then the cavity structure 6 is covered with the N-type semiconductor of an integrated structure to form the film bulk acoustic resonator. According to the manufacturing method of the film bulk acoustic resonator provided by the embodiment of the present disclosure, there is no need to etch sacrificial materials to form the cavity structure 6, thereby reducing probability of device reliability deterioration due to etching sacrificial materials.

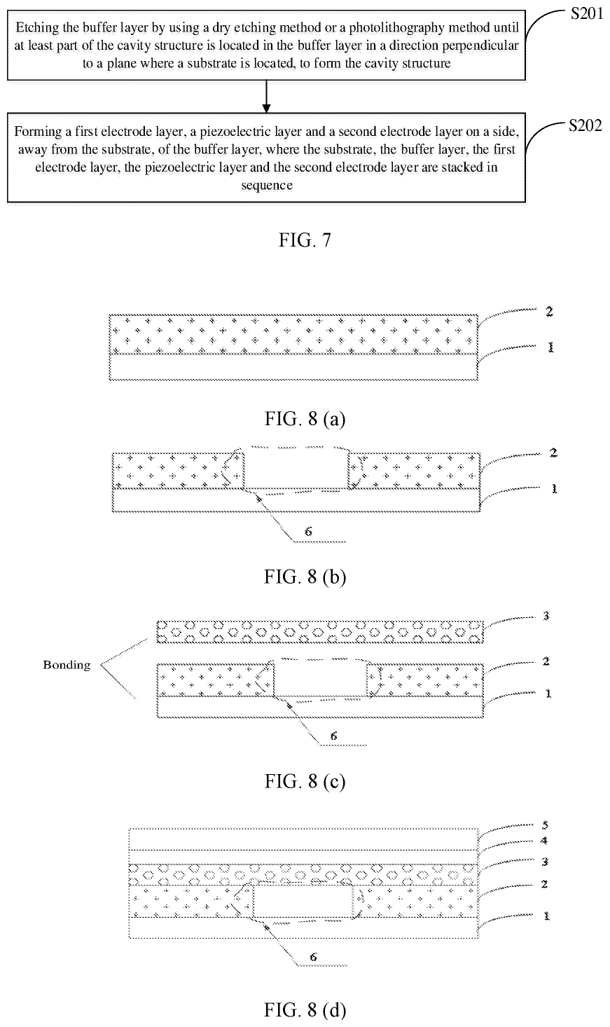

Specifically, FIG. 7 is a schematic flowchart of a manufacturing method for a film bulk acoustic resonator according to another embodiment of the present disclosure. As shown in FIG. 7, the step of forming a cavity structure 6 by using an etching process includes the following steps.

Step S201: etching the buffer layer by using a dry etching method or a photolithography method until at least part of the cavity structure is located in the buffer layer in a direction perpendicular to a plane where a substrate is located, to form the cavity structure.

Step S202: forming a first electrode layer, a piezoelectric layer and a second electrode layer on a side, away from the substrate, of the buffer layer, where the substrate, the buffer layer, the first electrode layer, the piezoelectric layer and the second electrode layer are stacked in sequence.

Exemplarily, a material of the buffer layer 2 is silicon dioxide, and a silicon dioxide coating with a preset thickness is deposited on the substrate 1 for subsequent etching. The buffer layer 2 is etched by the dry etching method or the photolithography method, until the buffer layer 2 is penetrated in the direction perpendicular to the plane where the substrate 1 is located (that is, an interface of the buffer layer 2 and the substrate is reached in the direction perpendicular to the plane where the substrate 1 is located), so that the cavity structure 6 is formed. In this situation, the cavity structure 6 penetrates through the buffer layer 2 in the direction perpendicular to the plane where the substrate 1 is located.

In an optional embodiment, the step of forming a cavity structure 6 by using an etching process includes: etching a part of the buffer layer 2 by using a dry etching method or a photolithography method, (that is, there is a part of the buffer layer 2 remained in the direction perpendicular to the plane where the substrate is located) so as to form the cavity structure 6.

Specifically, the buffer layer 2 is etched from a side, close to the first electrode layer 3, of the buffer layer 2 to a side, close to the substrate 1, of the buffer layer 2, until the etching process is stopped at a first preset distance from the substrate in the direction perpendicular to the plane where the substrate 1 is located, so as to form the cavity structure 6. In this situation, the cavity structure 6 is a first slot that is on a side, close to the first electrode layer 3, of the buffer layer 2 and does not penetrate the buffer layer 2 in the direction perpendicular to the plane where the substrate 1 is located.

In some other embodiments, the step of forming a cavity structure 6 by using an etching process includes: etching the buffer layer 2 by using a dry etching method or a photolithography method, and continuously etching part of the substrate 1 after the buffer layer 2 is penetrated, so as to form the cavity structure 6.

Specifically, the buffer layer 2 is etched from a side, close to the first electrode layer 3, of the buffer layer 2 to a side, close to the substrate, of the buffer layer 2, until the buffer layer 2 is penetrated, and then the substrate is continuously etched, but is not penetrated through in the direction perpendicular to the plane where the substrate 1 is located. In this situation, a cavity area is a through slot penetrating through the buffer layer 2 and a second slot that is on a side, close to the buffer layer 2, of the substrate 1 and does not penetrate through the substrate 1 in the direction perpendicular to the plane where the substrate 1 is located.

In the embodiments of the present disclosure, the cavity area is formed by the dry etching method or the photolithography method. Compared with a wet etching method in the conventional art, etching precision is higher, purchasing power is smaller, and environmental friendliness is higher.

For example, taking that a cavity structure 6 penetrates through a buffer layer 2 in a direction perpendicular to a plane where a substrate 1 is located as an example, FIG. 8 (a) to FIG. 8 (d) are schematic flowcharts of a manufacturing method for a film bulk acoustic resonator according to yet still another embodiment of the present disclosure. As shown in FIG. 8 (a) to FIG. 8 (d), the buffer layer 2 is deposited on the substrate 1, and the buffer layer 2 is etched from a side, close to a first electrode layer 3, of the buffer layer 2 to a side, close to the substrate 1, of the buffer layer 2, by means of a dry etching method or a photolithography method, until the substrate 1 is reached in the direction perpendicular to the plane where the substrate 1 is located, to form a cavity area, which may be referred in FIG. 8 (a) and FIG. 8 (b).

Specifically, a patterned photoresist layer is disposed on a side, away from the substrate 1, of the buffer layer 2. An area where the patterned photoresist layer exposes the buffer layer 2 corresponds to a position where a cavity structure 6 is subsequently formed. After the cavity structure 6 is formed by photolithography, the photoresist layer is removed, then a structure shown in FIG. 8 (b) is obtained.

A first electrode layer 3 is bonded to the buffer layer 2, which may be referred in FIG. 8 (c). Optionally, a piezoelectric layer 4 and a second electrode layer 5 are prepared on the first electrode layer 3, and the film bulk acoustic resonator is obtained, which may be referred in FIG. 8 (d).

It should be noted that bonding refers to a technology of a direct combination under a certain condition. It is a technology of bonding wafers into a whole by a van der Waals force or a molecular force or even an atomic force. The first electrode layer 3 is an integrated plate-shaped structure and needs to be attached to the buffer layer 2 below. Thus, the first electrode layer 3 is bonded to the buffer layer 2, so that the first electrode layer 3 and the buffer layer 2 may be tightly attached by utilizing a Van der Waals force or a molecular force or even an atomic force, thereby reducing a probability of the N-type semiconductor stripping from the buffer layer 2.

Since the cavity structure partially located in the buffer layer is first formed, and then the N-type semiconductor is arranged on the cavity structure, there is no need to etch sacrificial materials to form the cavity structure, thereby reducing probability of device reliability deterioration due to etching sacrificial materials.

It should be understood that the terms “include” and variations thereof used in the present disclosure are open ended, that is, “including but not limited to”. The term “an embodiment” means “at least one embodiment”; the term “another embodiment” means “at least one further embodiment”. In the specification, the schematic representation of the above terms does not necessarily refer to the same embodiment or example. Furthermore, the particular features, structures, materials, or characteristics described may be combined in any suitable manner in any one or more embodiments or examples. In addition, in the case of no contradiction, a person skilled in the art may combine different embodiments or examples described in the specification and features of different embodiments or examples.

The foregoing descriptions are merely preferred embodiments of the present disclosure, and are not intended to limit the present disclosure, and any modification, equivalent replacement, and the like, made within the spirit and principle of the present disclosure should be included within the protection scope of the present disclosure.

What is claimed is:

1. A film bulk acoustic resonator, comprising:
a substrate, a buffer layer, a first electrode layer, a piezoelectric layer, a second electrode layer stacked in sequence, and a cavity structure arranged between the substrate and the first electrode layer and at least partially located in the buffer layer, wherein
the first electrode layer comprises an N-type semiconductor.

2. The film bulk acoustic resonator according to claim 1, wherein the cavity structure comprises: a through slot penetrating through the buffer layer in a direction perpendicular to a plane where the substrate is located.

3. The film bulk acoustic resonator according to claim 1, wherein the first electrode layer further comprises: a metal synergistic resistance reduction layer disposed on a side, close to the buffer layer, of the N-type semiconductor.

4. The film bulk acoustic resonator according to claim 3, wherein the metal synergistic resistance reduction layer comprises any one of a molybdenum (Mo) layer, a cerium (Ce) layer, and a cobalt (Co) layer.

5. The film bulk acoustic resonator according to claim 1, wherein the N-type semiconductor comprises an N-type silicon carbide substrate or a heavily-doped N-type silicon carbide substrate.

6. The film bulk acoustic resonator according to claim 1, wherein the second electrode layer comprises: a metal sub-layer and a heavily-doped semiconductor stacked in sequence, and the metal sub-layer is located on a side, away from the substrate, of the heavily-doped semiconductor.

7. The film bulk acoustic resonator according to claim 6, wherein a material of the metal sub-layer comprises aluminum (Al) or copper (Cu).

8. The film bulk acoustic resonator according to claim 6, wherein a material of the heavily-doped semiconductor comprises a heavily-doped gallium nitride or a heavily-doped aluminum gallium nitride.

9. The film bulk acoustic resonator according to claim 1, wherein a material of the buffer layer comprises silicon dioxide.

10. The film bulk acoustic resonator according to claim 1, wherein a material of the piezoelectric layer comprises aluminum nitride.

11. A manufacturing method for a film bulk acoustic resonator, comprising:
forming a buffer layer on a substrate;
forming a cavity structure by using an etching process; and
forming a first electrode layer, a piezoelectric layer and a second electrode layer on a side, away from the substrate, of the buffer layer, wherein the substrate, the buffer layer, the first electrode layer, the piezoelectric layer and the second electrode layer are stacked in sequence;
wherein the cavity structure is arranged between the substrate and the first electrode layer, at least part of the cavity structure is located in the buffer layer; and
the first electrode layer comprises an N-type semiconductor.

12. The manufacturing method for the film bulk acoustic resonator according to claim 11, wherein the forming a cavity structure by using an etching process comprises:
at least etching the buffer layer by using a dry etching method or a photolithography method, until at least part of the cavity structure is located in the buffer layer in a direction perpendicular to a plane where the substrate is located, to form the cavity structure.

13. The manufacturing method for the film bulk acoustic resonator according to claim 11, wherein the forming the first electrode layer on the side, away from the substrate, of the buffer layer comprises:
bonding the first electrode layer to the buffer layer.

14. The manufacturing method for the film bulk acoustic resonator according to claim 11, wherein the forming a first electrode layer, a piezoelectric layer and a second electrode layer on a side, away from the substrate, of the buffer layer, wherein the substrate, the buffer layer, the first electrode layer, the piezoelectric layer and the second electrode layer are stacked in sequence comprises:
sequentially forming, after a stacked structure of the substrate, the buffer layer and the first electrode layer being manufactured, the piezoelectric layer and the second electrode layer on a side, away from the buffer layer, of the first electrode layer.

15. The manufacturing method for the film bulk acoustic resonator according to claim 11, wherein the forming a first electrode layer, a piezoelectric layer and a second electrode layer on a side, away from the substrate, of the buffer layer, wherein the substrate, the buffer layer, the first electrode layer, the piezoelectric layer and the second electrode layer are stacked in sequence comprises:
respectively manufacturing a stacked structure of the substrate and the buffer layer, and a stacked structure of the first electrode layer, the piezoelectric layer and the second electrode layer; and
bonding the buffer layer and the first electrode layer face to face.
